(19) United States
(12) Patent Application Publication
(10) Pub. No.: US 2025/0364768 A1
(43) Pub. Date: Nov. 27, 2025

(54) GAS LASER DEVICE AND ELECTRONIC DEVICE MANUFACTURING METHOD

(71) Applicant: Gigaphoton Inc., Tochigi (JP)

(72) Inventors: Takuya WARATANI, Tochigi (JP); Shinichi MATSUMOTO, Tochigi (JP); Kenshiro NAGAHAMA, Tochigi (JP); Yuki KAWASHIMA, Tochigi (JP)

(73) Assignee: Gigaphoton Inc., Tochigi (JP)

(21) Appl. No.: 19/291,557

(22) Filed: Aug. 5, 2025

Related U.S. Application Data
(63) Continuation of application No. PCT/JP2023/010410, filed on Mar. 16, 2023.

(51) Int. Cl. H01S 3/034; G03F 7/00; H01L 21/268

(52) U.S. Cl. CPC H01S 3/034; G03F 7/70025; H01L 21/268

(57) ABSTRACT

A gas laser device includes a chamber device including a pair of electrodes at an internal space thereof to be filled with a laser gas and configured to output, through a window to an outside thereof, light generated from the laser gas when a voltage is applied to the electrodes; a shutter arranged outside the chamber device and configured to be capable of shielding the light; a movement mechanism capable of moving the shutter onto an optical path of the light and a first retraction position outside the optical path of the light; and a coupling portion capable of coupling an optical component capable of receiving the light to the shutter. Here, the optical component is positioned on the optical path in a state in which the shutter is positioned at the first retraction position when the coupling portion is coupled to the optical component.

### CROSS-REFERENCE TO RELATED APPLICATIONS

The present application is a continuation application of International Application No. PCT/JP2023/010410, filed on Mar. 16, 2023, the entire contents of which are hereby incorporated by reference.

### BACKGROUND

### 1. Technical Field

The present disclosure relates to a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248.0 nm and an ArF excimer laser device for outputting laser light having a wavelength of about 193.4 nm are used.

The KrF excimer laser device and the ArF excimer laser device each have a large spectral line width of about 350 μm to 400 μm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. In the following, a gas laser device with a narrowed spectral line width is referred to as a line narrowing gas laser device.

### LIST OF DOCUMENTS

### Patent Documents

Patent Document 1: Japanese Patent Application Publication No. H8-174260
Patent Document 2: Japanese Patent No. 4243686
Patent Document 3: Japanese Patent Application Publication No. 2021-41429

### SUMMARY

A gas laser device according to an aspect of the present disclosure includes a chamber device including a pair of electrodes at an internal space thereof to be filled with a laser gas and configured to output, through a window to an outside thereof, light generated from the laser gas when a voltage is applied to the electrodes; a shutter arranged outside the chamber device and configured to be capable of shielding the light; a movement mechanism capable of moving the shutter onto an optical path of the light and a first retraction position outside the optical path of the light; and a coupling portion capable of coupling an optical component capable of receiving the light to the shutter. Here, the optical component is positioned on the optical path in a state in which the shutter is positioned at the first retraction position when the coupling portion is coupled to the optical component.

An electronic device manufacturing method according to an aspect of the present disclosure includes generating laser light using a gas laser device, outputting the laser light to an exposure apparatus, and exposing a photosensitive substrate to the laser light in the exposure apparatus to manufacture an electronic device. Here, the gas laser device includes a chamber device including a pair of electrodes at an internal space thereof to be filled with a laser gas and configured to output, through a window to an outside thereof, light generated from the laser gas when a voltage is applied to the electrodes; a shutter arranged outside the chamber device and configured to be capable of shielding the light; a movement mechanism capable of moving the shutter onto an optical path of the light and a first retraction position outside the optical path of the light; and a coupling portion capable of coupling an optical component capable of receiving the light to the shutter. The optical component is positioned on the optical path in a state in which the shutter is positioned at the first retraction position when the coupling portion is coupled to the optical component.

### BRIEF DESCRIPTION OF THE DRAWINGS

Embodiments of the present disclosure will be described below merely as examples with reference to the accompanying drawings.

FIG. 1 is a schematic view showing a schematic configuration example of an entire electronic device manufacturing apparatus.

FIG. 2 is a schematic view showing a schematic configuration example of an entire gas laser device of a comparative example.

FIG. 3 is a view of the gas laser device of FIG. 2 viewed from above.

FIG. 4 is a front view of a shutter unit viewed from a chamber side.

FIG. 5 is a view of the shutter unit viewed from the same viewpoint as in FIG. 2.

FIG. 6 is a view showing an open state of a shutter.

FIG. 7 is a view showing a state during maintenance from the outside of the gas laser device.

FIG. 8 is a view showing a state in which a power monitor is arranged during maintenance viewed from above.

FIG. 9 is a front view of the shutter unit of a first embodiment viewed from the chamber side.

FIG. 10 is an enlarged view of the vicinity of a coupling portion.

FIG. 11 is a view showing a state in which a power meter is being coupled to the shutter.

FIG. 12 is a view showing a state in which the shutter is positioned on the optical path of laser light during maintenance.

FIG. 13 is a view showing a state in which the power meter is coupled.

FIG. 14 is a view showing a state in which the power meter is positioned on the optical path.

FIG. 15 is an enlarged view of the vicinity of the coupling portion in a modification of the first embodiment.

FIG. 16 is a view of the shutter unit in the gas laser device of a second embodiment viewed from the same viewpoint as in FIG. 9.

### DESCRIPTION OF EMBODIMENTS

1. Description of electronic device manufacturing apparatus used in exposure process for electronic device
2. Description of comparative example
   2.1 Configuration
   2.2 Operation
   2.3 Problem
3. Description of first embodiment
   3.1 Configuration
   3.2 Maintenance procedure
   3.3 Effect
   3.4 Modification
4. Description of second embodiment
   4.1 Configuration
   4.2 Effect

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numeral, and duplicate description thereof is omitted.

### 1. Description of Electronic Device Manufacturing Apparatus

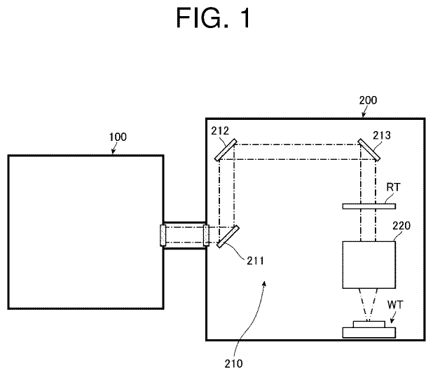

Used in Exposure Process for Electronic Device FIG. 1 is a schematic view showing a schematic configuration example of an entire electronic device manufacturing apparatus used in an exposure process for an electronic device. As shown in FIG. 1, the manufacturing apparatus used in the exposure process includes a gas laser device 100 and an exposure apparatus 200. The exposure apparatus 200 includes an illumination optical system 210 including a plurality of mirrors 211, 212, 213 and a projection optical system 220. The illumination optical system 210 illuminates a reticle pattern of a reticle stage RT with laser light incident from the gas laser device 100. The projection optical system 220 causes the laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 200 synchronously translates the reticle stage RT and the workpiece table WT to expose the workpiece to the laser light reflecting the reticle pattern. Through the exposure process as described above, a device pattern is transferred onto the semiconductor wafer, thereby a semiconductor device, which is an electronic device, can be manufactured.

### 2. Description of Comparative Example

### 2.1 Configuration

The gas laser device of a comparative example will be described. The comparative example of the present disclosure is an example recognized by the applicant as known only by the applicant, and is not a publicly known example admitted by the applicant.

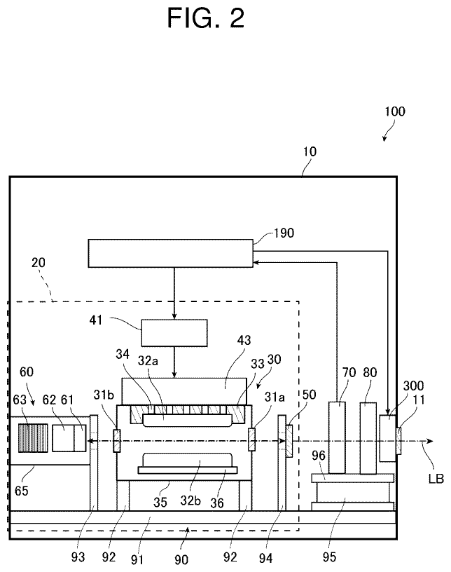

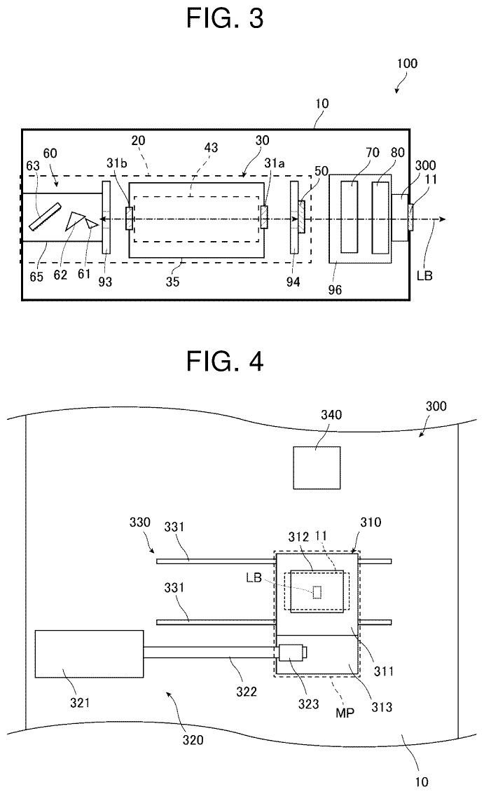

FIG. 2 is a schematic view showing a schematic configuration example of the entire gas laser device 100 of the present example, and FIG. 3 is a view of the gas laser device 100 of FIG. 2 viewed from above. The gas laser device 100 is, for example, an ArF excimer laser device using a mixed gas including argon (Ar), fluorine (F₂), and neon (Ne). The gas laser device 100 outputs laser light LB having a center wavelength of about 193.4 nm. Here, the gas laser device 100 may be a gas laser device other than the ArF excimer laser device, and may be, for example, a KrF excimer laser device using a mixed gas including krypton (Kr), F₂, and Ne. In this case, the gas laser device 100 outputs the laser light LB having a center wavelength of about 248.0 nm. The mixed gas containing Ar, F₂, and Ne which is a laser medium and the mixed gas containing Kr, F₂, and Ne which is a laser medium may be each referred to as a laser gas. In the mixed gas used in each of the ArF excimer laser device and the KrF excimer laser device, helium (He) may be used instead of Ne.

The gas laser device 100 of the present example includes a housing 10, a laser oscillator 20, a monitor module 70, a beam performance monitor 80, a shutter unit 300, a support member 90, and a processor 190 as a main configuration.

The laser oscillator 20 is a device that oscillates laser light LB, and includes a chamber device 30, a charger 41, a pulse power module 43, a line narrowing module 60, and an output coupling mirror 50 as a main configuration.

In FIG. 2, the internal configuration of the chamber device 30 is shown as viewed from a direction substantially perpendicular to the travel direction of the laser light LB. The chamber device 30 includes a chamber 35, a pair of windows 31a, 31b, a pair of electrodes 32a, 32b, an insulating portion 33, a feedthrough 34, and an electrode holder portion 36 as a main configuration.

The chamber 35 is a housing filled with the laser gas. The laser gas is supplied from a laser gas supply device (not shown) to the internal space of the chamber 35 through a pipe. The internal space of the chamber 35 is a space in which light is generated by excitation of the laser medium in the laser gas. This light travels to the windows 31a, 31b.

The window 31a is arranged at a wall of the chamber 35 on the front side in the travel direction of the laser light LB, and the window 31b is arranged at a wall of the chamber 35 on the rear side in the travel direction. The windows 31a, 31b may be inclined at the Brewster angle with respect to the travel direction of the laser light LB so that P polarization of the laser light is suppressed from being reflected.

The electrodes 32a, 32b are discharge electrodes for exciting the laser medium by glow discharge due to a high voltage applied therebetween. The electrodes 32a, 32b are arranged to face each other at the internal space of the chamber 35. In the present example, the electrode 32a is the cathode and the electrode 32b is the anode. The longitudinal direction of the electrodes 32a, 32b is along the travel direction of the laser light LB. The space between the electrode 32a and the electrode 32b in the chamber 35 is sandwiched by the window 31a and the window 31b.

The electrode 32a is supported by the insulating portion 33 including an insulator. The insulating portion 33 blocks an opening formed in the chamber 35. Further, the feedthrough 34 made of a conductive member is arranged in the insulating portion 33. The feedthrough 34 applies a voltage, to the electrode 32a, supplied from the pulse power module 43. The electrode 32b is supported by the electrode holder portion 36 and is electrically connected to the electrode holder portion 36. The electrode holder portion 36 is electrically connected to the chamber 35 by wirings (not shown), and the chamber 35 is electrically connected to the ground. Therefore, the electrode 32b is electrically connected to the ground.

The charger 41 is a DC power source device that charges a capacitor (not shown) provided in the pulse power module 43 with a predetermined voltage. The charger 41 is arranged outside the chamber 35 and is connected to the pulse power module 43. The pulse power module 43 includes a switch (not shown) controlled by the processor 190. The pulse power module 43 is a voltage application circuit that, when the switch is turned ON from OFF by the control, boosts the voltage applied from the charger 41 to generate a pulse high voltage, and applies the high voltage to the electrode 32a. When the high voltage is applied to the electrode 32a, glow discharge occurs between the electrode 32a and the electrode 32b, and the laser medium is excited. The light generated by the excitation of the laser medium is transmitted through the windows 31a, 31b and is output to the outside of the chamber 35.

The line narrowing module 60 includes a housing 65, prisms 61, 62, and a grating 63 as a main configuration. The prisms 61, 62 and the grating 63 are arranged at the internal space of the housing 65. An opening is formed in the housing 65 at a position facing the window 31b, and the light output from the window 31b of the chamber 35 propagates from the opening into the housing 65.

The prisms 61, 62 expand the beam width of the light output from the window 31b and causes the light to be incident on the grating 63. Further, the prisms 61, 62 return the light reflected from the grating to the internal space of the chamber 35 through the window 31b. At least one of the prisms 61, 62 is supported by a rotation stage (not shown), and is rotated by the rotation of the rotation stage. The incident angle of the light with respect to the grating 63 is changed by the rotation of the prisms 61, 62. Therefore, by rotating the prisms 61, 62, the wavelength of the light returning from the grating 63 to the chamber 35 via the prisms 61, 62 can be selected. Although FIG. 2 shows an example in which two prisms 61, 62 are arranged, one prism may be arranged or three or more prisms may be arranged. In the present example, the prism 61 is arranged on the chamber 35 side, and the prism 62 is arranged on the grating 63 side.

The surface of the grating 63 is configured of a material having a high reflectance, and a large number of grooves are formed on the surface at predetermined intervals. The grating 63 is a dispersive optical element. The sectional shape of each groove is, for example, a right-angled triangle. The light incident on the grating 63 from the prism 62 is reflected by these grooves and diffracted in a direction corresponding to the wavelength of the light. The grating 63 is arranged in the Littrow arrangement, which causes the incident angle of the light incident on the grating 63 from the prism 62 to coincide with the diffraction angle of the diffracted light having a desired wavelength. Thus, light having the desired wavelength returns into the chamber 35 via the prisms 61, 62.

The output coupling mirror 50 faces the window 31a, transmits a part of the laser light LB output from the window 31a, and reflects another part thereof to return to the internal space of the chamber 35 through the window 31a. The output coupling mirror 50 is arranged at the internal space of the housing 10.

The grating 63 and the output coupling mirror 50 arranged with the chamber 35 interposed therebetween configure a Fabry-Perot resonator, and the chamber 35 is arranged on the optical path of the resonator.

The monitor module 70 is arranged on the optical path of the laser light LB transmitted through the output coupling mirror 50. The monitor module 70 includes a beam splitter (not shown) and an optical sensor (not shown) such as a photodiode. The beam splitter transmits the laser light LB transmitted through the output coupling mirror 50 at a high transmittance, and reflects a part of the laser light LB toward the optical sensor. The optical sensor measures the pulse energy of the entering laser light LB. The optical sensor is electrically connected to the processor 190, and outputs a signal indicating the measured pulse energy to the processor 190. The processor 190 controls the voltage to be applied to the electrodes 32a, 32b based on the signal.

A beam performance monitor 80 is arranged on the optical path opposite to the output coupling mirror 50 side with respect to the monitor module 70. The beam performance monitor 80 includes a beam splitter (not shown) and at least one of optical measurement instruments such as a beam profiler, a pointing measurement instrument, and a polarization measurement instrument. The beam splitter of the beam performance monitor 80 transmits the laser light LB transmitted through the beam splitter of the monitor module 70 at a high transmittance, and reflects a part of the laser light LB toward the optical measurement instrument. The optical measurement instrument measures a characteristic of the entering laser light LB, and outputs a signal related to the characteristic. This signal is transmitted to an external monitor or the like, for example, and information related to the laser light LB is displayed on the monitor or the like.

The shutter unit 300 is provided on the optical path opposite to the monitor module 70 side with respect to the beam performance monitor 80. The shutter unit 300 is supported by the housing 10. The laser light LB transmitted through the beam splitter of the beam performance monitor 80 enters the shutter unit 300. The shutter unit 300 is electrically connected to the processor 190, and is controlled by the processor 190 into a closed state in which the laser light LB is shielded and an open state in which the laser light LB is transmitted. Details of the shutter unit 300 will be described later.

An output window 11 is provided on the housing 10 on the optical path of the laser light LB at a position overlapping the shutter unit 300. Light passing through the shutter unit 300 is output from the output window 11 to the outside of the housing 10. The laser light LB is, for example, pulse laser light having a center wavelength of 193.4 nm.

The support member 90 includes a bottom plate member 91, a chamber support portion 92, a line narrowing module support portion 93, an output coupling mirror support portion 94, and an optical plate support portion 95. The bottom plate member 91 fixes one end and the other end of the housing 10 along the travel direction of the laser light LB. The chamber support portion 92, the line narrowing module support portion 93, the output coupling mirror support portion 94, and the optical plate support portion 95 are arranged on the bottom plate member 91. The chamber support portion 92 supports the chamber 35. The line narrowing module support portion 93 supports the line narrowing module 60. An opening indicated by a dotted line is provided to the line narrowing module support portion 93 at a position facing the window 31b, and causes the light output from the window 31b to pass therethrough. The output coupling mirror support portion 94 supports the output coupling mirror 50. An opening indicated by a dotted line is provided to the output coupling mirror support portion 94 at a position facing the window 31a, and causes the light output from the window 31a to pass therethrough. The optical plate support portion 95 supports the optical plate 96. The optical plate 96 is a plate-like member, and the monitor module 70 and the beam performance monitor 80 are arranged on the optical plate 96.

The processor 190 of the present disclosure is a processing device including a storage device in which a control program is stored and a central processing unit (CPU) that executes the control program. The processor 190 is specifically configured or programmed to perform various processes included in the present disclosure and controls the entire gas laser device 100. The processor 190 is electrically connected to an exposure processor (not shown) of the exposure apparatus 200, and transmits and receives various signals to and from the exposure processor.

Next, the shutter unit 300 will be described.

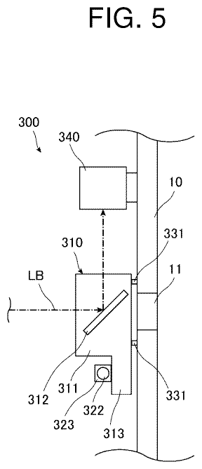

FIG. 4 is a front view of the shutter unit 300 viewed from the chamber 35 side, and FIG. 5 is a view of the shutter unit 300 viewed from the same viewpoint as in FIG. 2. The shutter unit 300 includes a shutter 310, an air cylinder 320, a guide 330, and a damper 340 as a main configuration.

The shutter 310 is a member capable of shielding the laser light LB transmitted through the beam performance monitor 80. The shutter 310 includes a shutter main body 311 and a mirror 312 as a main configuration. The shutter main body 311 is a frame-shaped member and holds the mirror 312. Further, a plate-shaped extension portion 313 extending downward is connected to the shutter main body 311. The mirror 312 is a member that totally reflects the laser light LB incident thereon. The mirror 312 has a reflection surface inclined upward by 45 degrees, and reflects the laser light LB upward when the laser light LB is incident on the mirror 312 from the beam performance monitor 80 as shown in FIG. 5. The damper 340 is provided above the output window 11, and absorbs the laser light LB when the mirror 312 reflects the laser light LB upward, and converts it into thermal energy.

The guide 330 includes a pair of linear rails 331 having the longitudinal direction thereof extending in the horizontal direction, and each of the rails 331 is fixed to the housing 10. A slider (not shown) provided on the shutter main body 311 is movably fitted to each of the rails 331. Thus, the shutter 310 can move linearly along the rails 331. In the present embodiment, the rails 331 are provided at positions sandwiching the output window 11 in front view.

The air cylinder 320 includes a drive unit 321 and a rod 322 as a main configuration. The drive unit 321 is electrically connected to the processor 190. One side of the rod 322 is inserted into the drive unit 321, and the drive unit 321 can move the rod 322 along the longitudinal direction thereof by adjusting the internal air pressure by control of the processor 190. The air cylinder 320 is fixed to the housing 10 so that the longitudinal direction of the rod 322 is along the longitudinal direction of the rails 331 of the guide 330. A connection portion 323 is provided at the other end of the rod 322, and the connection portion 323 is fixed to the extension portion 313 of the shutter 310. Therefore, the movement of the rod 322 causes the shutter 310 to move along the longitudinal direction of the rails 331.

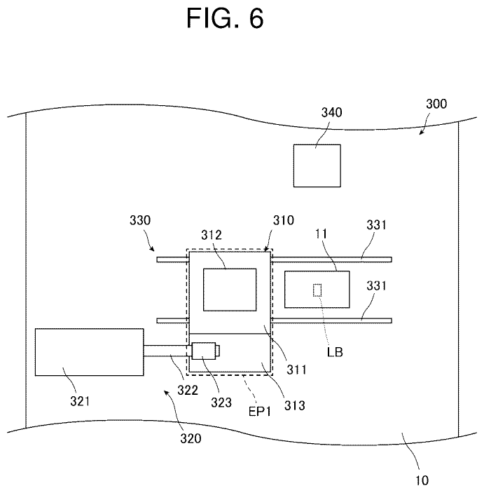

FIG. 4 is a view showing the closed state in which the shutter 310 blocks the output window 11 and shields the laser light LB. In this state, the shutter 310 is positioned on the optical path of the laser light LB. In FIG. 4, the laser light LB radiated to the shutter 310 is indicated by a dotted line. The position of the shutter 310 at this time is referred to as a shield position MP indicated by a broken line. FIG. 6 is a view showing the open state in which the shutter 310 does not shield the output window 11. In this state, the shutter 310 is positioned outside the optical path of the laser light LB. When the position outside the optical path is a first retraction position EP1 indicated by a broken line, the air cylinder 320 is a movement mechanism capable of linearly moving the shutter 310 to the shield position MP and the first retraction position EP1 outside the optical path of the laser light LB.

### 2.2 Operation

Next, operation of the gas laser device 100 of the comparative example will be described.

The laser gas is supplied to the internal space of the chamber 35 from the laser gas supply device (not shown) before the gas laser device 100 outputs the laser light LB. At this time, the processor 190 may control the shutter unit 300 so that the shutter 310 is positioned at the shield position MP.

When the gas laser device 100 outputs the laser light LB, the processor 190 receives a signal indicating a target energy Et and a light emission trigger signal from the exposure processor (not shown) of the exposure apparatus 200. At this time, the processor 190 controls the shutter unit 300 so that the shutter 310 is positioned at the first retraction position EP1. The target energy Et is a target value E of the energy of the laser light to be used in the exposure process. The processor 190 sets a predetermined charge voltage to the charger 41 so that the energy E of the laser light LB becomes the target energy Et, and turns ON the switch of the pulse power module 43 in synchronization with the light emission trigger signal. Thus, the pulse power module 43 generates a pulse high voltage from the electric energy held in the charger 41, and applies the high voltage between the electrode 32a and the electrode 32b. When the high voltage is applied, glow discharge occurs between the electrode 32a and the electrode 32b, the laser medium contained in the laser gas between the electrode 32a and the electrode 32b is brought into an excited state, and light is emitted when the laser medium returns to the ground state. The emitted light resonates between the grating 63 and the output coupling mirror 50, and is amplified every time passing through the discharge space at the internal space of the chamber 35, so that laser oscillation occurs. A part of the laser light LB is transmitted through the output coupling mirror 50. Most of the laser light LB transmitted through the output coupling mirror 50 is transmitted through the monitor module 70 and the beam performance monitor 80, and enters the shutter unit 300. When the shutter 310 is positioned at the first retraction position EP1, the laser light LB entering the shutter unit 300 is transmitted through the output window 11 and output from the gas laser device 100. The laser light LB output from the gas laser device 100 enters the exposure apparatus 200.

At this time, as described above, the monitor module 70 measures the energy E of the laser light LB and outputs a signal indicating the measured energy E of the laser light LB to the processor 190. Based on the signal, the processor 190 performs feedback control on the charge voltage of the charger 41 so that a difference ΔE between the energy E and the target energy Et falls within an allowable range.

### 2.3 Problem

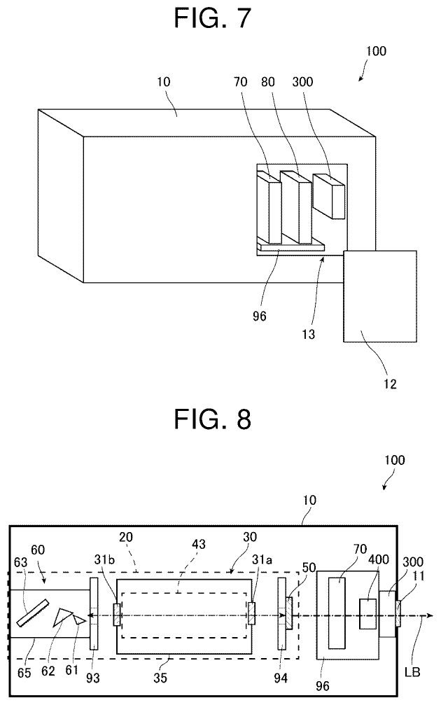

Maintenance such as adjustment or replacement of the monitor module 70 is performed in some cases. FIG. 7 is a view showing a state during maintenance viewed from the outside of the gas laser device 100. During maintenance of the monitor module 70, the maintenance panel 12 of the housing 10 of the gas laser device 100 is removed. As a result, a maintenance opening 13 appears. Maintenance of the monitor module 70 is performed through the maintenance opening 13. During maintenance of the monitor module 70, the measurement value of the monitor module 70 may be calibrated. In this case, calibration is performed based on the power of the light transmitted through the monitor module 70. Therefore, a power meter for measuring the power of the laser light LB is required to be arranged on the optical path of the laser light LB transmitted through the monitor module 70. However, since the beam performance monitor 80 is arranged downstream of the laser light LB of the monitor module 70, it is difficult to arrange the power meter. Therefore, as shown in FIG. 8, the beam performance monitor 80 is removed, and a power meter 400 is arranged at the position where the beam performance monitor 80 was arranged.

However, it takes time to remove the beam performance monitor 80 during maintenance of the monitor module 70. Further, when the beam performance monitor 80 is reinstalled after maintenance of the monitor module 70, it may take time to finely adjust the position of the beam performance monitor 80. There is a concern that the operation efficiency of the gas laser device 100 is lowered due to downtime during such maintenance. Further, even in a case that the beam performance monitor 80 is removed and an optical component other than the power meter 400 that receives the laser light LB is arranged, there is a concern that the operation efficiency of the gas laser device 100 is lowered.

Therefore, in the following embodiments, a gas laser device capable of arranging an optical component for receiving the laser light LB while reducing downtime is exemplified.

### 3. Description of First Embodiment

Next, the gas laser device 100 of a first embodiment will be described. Any component same as that described above is denoted by an identical reference sign, and duplicate description thereof is omitted unless specific description is needed. Further, in some drawings, a part of a member may be omitted or simplified for easy viewing.

### 3.1 Configuration

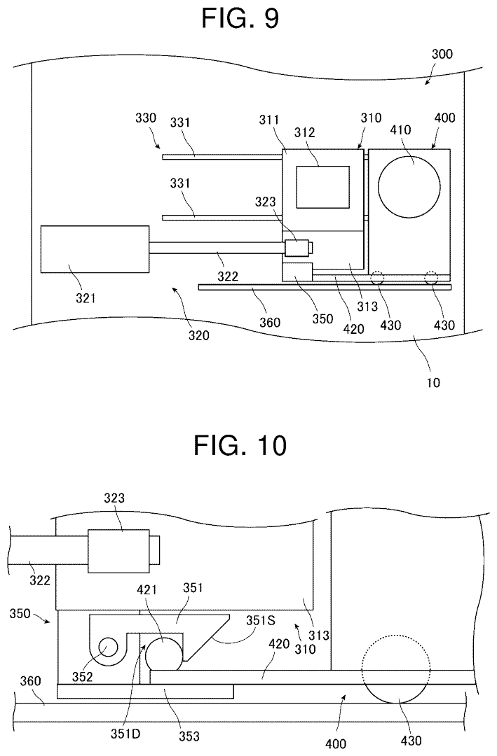

FIG. 9 is a front view of the shutter unit 300 of the present embodiment viewed from the chamber 35 side. The gas laser device 100 of the present embodiment is mainly different from the gas laser device 100 of the comparative example in that the shutter unit 300 includes a coupling portion 350. Here, FIG. 9 shows a state in which the shutter 310 is positioned at the shield position MP.

The coupling portion 350 is a member capable of coupling the power meter 400 to the shutter 310. The power meter 400 is an optical component that receives the laser light LB, and is an optical measurement instrument that can measure the power of the received laser light LB. In the present embodiment, the coupling portion 350 is provided at the extension portion 313 of the shutter 310. The power meter 400 moves together with the shutter 310 in a state of being coupled to the shutter 310 by the coupling portion 350.

In the present embodiment, the shutter unit 300 includes an optical component support portion 360 fixed to the housing 10. The optical component support portion 360 is a member that supports the power meter 400. The optical component support portion 360 may have a plate shape.

The power meter 400 includes a light receiving unit 410 that receives the laser light LB, an arm portion 420, and ball casters 430 as a main configuration. The power meter 400 outputs a signal related to the power of the laser light LB when the light receiving unit 410 receives the laser light LB. The ball casters 430 roll on the optical component support portion 360. Therefore, a frictional resistance during movement of the power meter 400 is reduced. The optical component support portion 360 may be provided with grooves through which the ball casters 430 roll. The arm portion 420 extends in the horizontal direction from below the power meter 400, and has a distal end thereof coupled to the coupling portion 350.

FIG. 10 is an enlarged view of the vicinity of the coupling portion 350. As shown in FIG. 10, a protrusion 421 protruding upward is provided at the distal end of the arm portion 420. In the present embodiment, the protrusion 421 has a substantially spherical shape. The coupling portion 350 includes a hook member 351 and a base portion 353 as a main configuration. The hook member 351 is rotatably fixed to a shaft member 352. Further, an inclined portion 351S is provided at an end portion of the hook member 351 opposite to the shaft member 352 side, and a recessed portion 351D is formed in the hook member 351 between the shaft member 352 and the inclined portion 351S. The hook member 351 is biased by a spring (not shown) so that the inclined portion 351S faces downward without particularly applying a force to the hook member 351. The base portion 353 is a member that extends in the horizontal direction to a position overlapping the inclined portion 351S below the hook member 351 with a predetermined distance with respect to the hook member 351. As shown in FIG. 10, when the power meter 400 is coupled to the shutter 310 by the coupling portion 350, the base portion 353 supports the lower surface of the arm portion 420, and the protrusion 421 enters the recessed portion 351D.

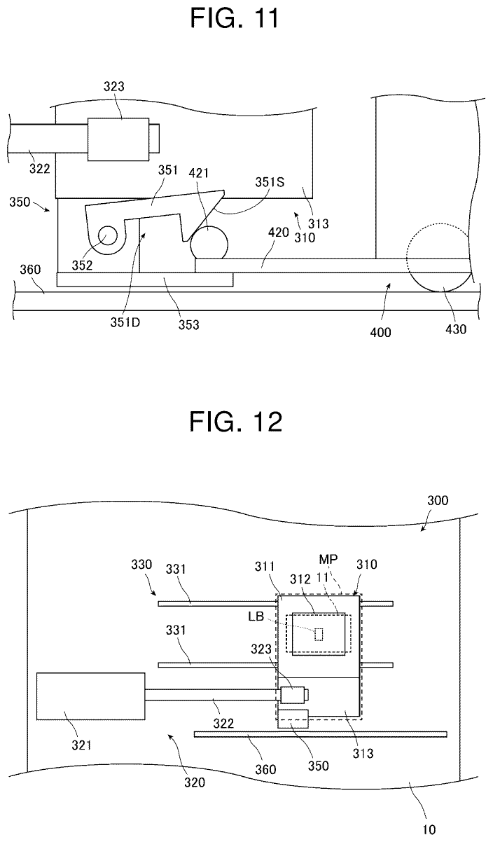

FIG. 11 is a view showing a state in which the power meter 400 is being coupled to the shutter 310. As shown in FIG. 11, when the power meter 400 is being coupled to the shutter 310, the power meter 400 is pressed against the coupling portion 350. Owing to this pressing, the protrusion 421 slides on the inclined portion 351S of the hook member 351, and the hook member 351 rotates about the shaft member 352 to lift the distal end of the hook member 351. At this time, since the protrusion 421 has a substantially spherical shape as described above, the protrusion 421 is more likely to slide on the inclined portion 351S than when the protrusion 421 has a columnar shape. At this time, since the base portion 353 supports the arm portion 420, lowering of the arm portion 420 is suppressed, and the protrusion 421 pushes up the hook member 351 appropriately. When the power meter 400 is further pressed against the coupling portion 350, the protrusion 421 enters the recessed portion 351D, and the hook member 351 returns to the original position, and as shown in FIG. 10, the power meter 400 is coupled to the shutter 310.

### 3.2 Maintenance Procedure

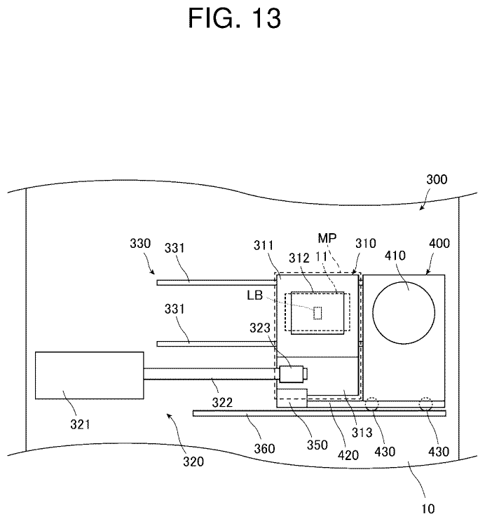

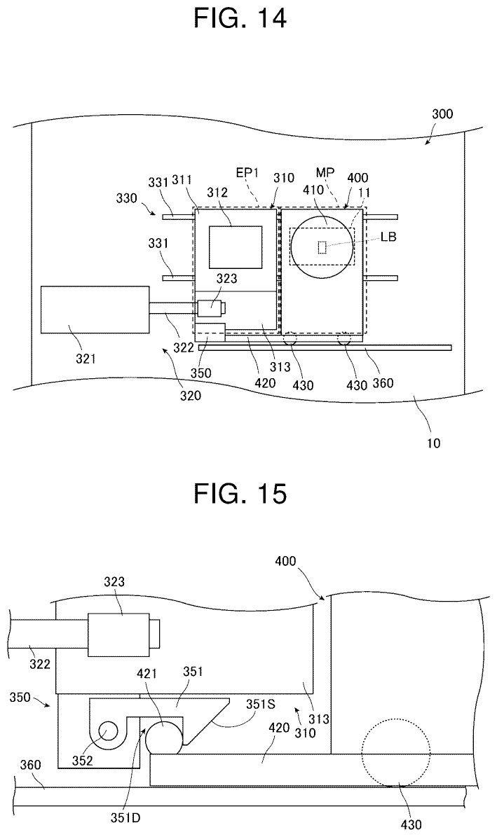

Next, a maintenance procedure will be described. First, as shown in FIG. 7, the maintenance panel 12 is removed and the maintenance opening 13 is exposed. In this state, generally, the output of the laser light LB from the laser oscillator 20 is stopped. Further, as shown in FIG. 12, the processor 190 controls the air cylinder 320 of the shutter unit 300 so that the shutter 310 is positioned at the shield position MP. In this state, the coupling portion 350 can attach and detach the power meter 400. Therefore, via the maintenance opening 13 as described with reference to FIG. 11, the protrusion 421 is hooked on the hook member 351 of the coupling portion 350, and the power meter 400 is coupled to the shutter 310 as shown in FIG. 13. Next, as shown in FIG. 14, the processor 190 controls the air cylinder 320 so that the shutter 310 moves to the first retraction position EP1. At this time, the power meter 400 coupled to the shutter 310 by the coupling portion 350 moves together with the shutter 310 and moves to the shield position MP, which is on the optical path of the laser light LB. In FIG. 14, an irradiation position of the laser light LB is indicated by a dotted line.

In a state in which the power meter 400 is located at the shield position MP, the processor 190 causes the laser oscillator 20 to output the laser light LB. Most of the laser light LB passes through the beam splitters of the monitor module 70 and the beam performance monitor 80, and is received by the light receiving unit 410 of the power meter 400. When the light receiving unit 410 receives the laser light LB, the power meter 400 outputs a signal including data related to the power of the received laser light LB. At this time, the monitor module 70 also measures the power of a part of the laser light LB reflected by the beam splitter therein, and outputs a signal including the measurement result. Therefore, the monitor module 70 can be calibrated based on the signal from the power meter 400 and the signal from the monitor module 70.

After maintenance is completed, the processor 190 controls the air cylinder 320 of the shutter unit 300 so that the shutter 310 is positioned at the shield position MP again, thereby obtaining the state shown in FIG. 13. In this state, the power meter 400 is removed, thereby obtaining the state shown in FIG. 12. Thereafter, the maintenance panel 12 is attached and maintenance is completed.

### 3.3 Effect

The gas laser device 100 of the present embodiment includes the coupling portion 350 capable of coupling the power meter 400 to the shutter 310, and when the power meter 400 is coupled to the coupling portion 350, the power meter 400 is positioned on the optical path of the laser light LB with the shutter 310 positioned at the first retraction position EP1. Therefore, even without removing the beam performance monitor 80, the power meter 400 can receive the laser light LB and measure the power thereof, and it is possible to perform maintenance. Therefore, the time for removing the beam performance monitor 80 is unnecessary at the time of maintenance of the monitor module 70, and the time for reinstalling the beam performance monitor 80 after maintenance of the monitor module 70 is unnecessary. Therefore, according to the gas laser device 100 of the present embodiment, the power meter 400 for receiving the laser light LB can be arranged and the laser light LB can be measured while reducing the downtime.

Further, the coupling portion 350 can attach and detach the power meter 400 in a state in which the shutter 310 is positioned on the optical path. With such a configuration, the power meter 400 can be attached and detached without moving the shutter 310 to a position other than the shield position MP and the first retraction position EP1. Therefore, the control of the air cylinder 320 by the processor 190 can be simplified as compared with a case in which the shutter 310 moves to a position other than the shield position MP and the first retraction position EP1 when the power meter 400 is attached and detached.

### 3.4 Modification

Next, a modification of the present embodiment will be described. FIG. 15 is an enlarged view of the vicinity of the coupling portion 350 in the present modification. As shown in FIG. 15, the gas laser device 100 of the present modification is mainly different from the gas laser device 100 of the above-described embodiment in that the coupling portion 350 does not include the base portion 353.

In the present embodiment, a gap between the optical component support portion 360 and the arm portion 420 is approximately zero. Thus, in the present modification, most of the ball casters 430 are hidden within the main body of the power meter 400. Therefore, even though the base portion 353 is not provided, the optical component support portion 360 can support the arm portion 420.

According to the present modification, since the coupling portion 350 does not include the base portion 353, the configuration can be simplified as compared with the gas laser device 100 of the first embodiment.

### 4. Description of Second Embodiment

Next, the gas laser device 100 of a second embodiment will be described. Any component same as that described above is denoted by an identical reference sign, and duplicate description thereof is omitted unless specific description is needed. Further, in the drawings, a part of a member may be omitted or simplified for easy viewing.

### 4.1 Configuration

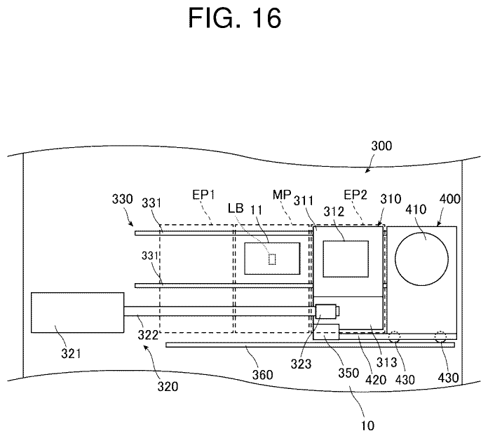

FIG. 16 is a view of the shutter unit 300 in the gas laser device 100 of the present embodiment viewed from the same viewpoint as in FIG. 9. As shown in FIG. 16, the gas laser device 100 of the present embodiment is mainly different from the gas laser device 100 of the first embodiment in that the rails 331 of the guide 330 and the optical component support portion 360 extend longer toward a side opposite to the first retraction position EP1 side with respect to the optical path than the rails 331 and the optical component support portion 360 of the first embodiment. In the present embodiment, the air cylinder 320 is capable of moving the shutter 310 to a second retraction position EP2 opposite to the first retraction position EP1 side with respect to the optical path. Therefore, in the present embodiment, the movable range of the rod 322 of the air cylinder 320 is larger than the movable range of the rod 322 in the first embodiment.

In the present embodiment, the power meter 400 can be attached and detached while the shutter 310 is positioned at the second retraction position EP2 during maintenance.

### 4.2 Effect

According to the gas laser device 100 of the present embodiment, as compared with the first embodiment, since the power meter 400 can be attached and detached in a state in which the shutter 310 is separated from the optical path, the power meter 400 can be easily attached and detached.

Although the present invention has been described based on the first embodiment, the modification thereof, and the second embodiment, the present invention is not limited thereto. For example, although an example in which the power meter 400 is used as the optical measurement instrument coupled to the shutter 310 by the coupling portion 350 has been described, the optical measurement instrument is not limited to the power meter, and other optical measurement instruments may be used as long as the laser light LB can be measured. Examples of such an optical measurement instrument include a biplanar for measuring the pulse width of the laser light LB. Further, the optical component coupled to the shutter 310 by the coupling portion 350 is not limited to the optical measurement instrument as long as the optical component can receive the laser light LB. Examples of such an optical component include an optical fiber member on which an optical fiber is mounted. The optical fiber is, for example, connected to a spectrometer which is arranged outside the gas laser device 100 and measures the spectrum of the laser light LB. Here, a fan-in device that reduces the diameter of the laser light LB and causes the laser light LB to propagate through the core of the optical fiber may be mounted on the optical fiber member.

Further, although an example in which the coupling portion 350 includes the hook member 351 on which the protrusion 421 provided at the optical measurement instrument such as the power meter 400 is hooked has been described, the coupling portion 350 is not limited to this example. For example, the coupling portion 350 may be a screw that is screwed into a screw hole provided in the optical measurement instrument.

Further, although an example in which the coupling portion 350 is provided at the shutter 310 has been described as an example, the coupling portion 350 may not be provided at the shutter 310 as long as the optical component such as the optical measurement instrument (e.g., the power meter 400) can be connected to the shutter 310. For example, the coupling portion 350 may be provided at the rod 322 or the connection portion 323 of the air cylinder 320. Even in this case, the optical measurement instrument is coupled to the shutter 310 via the rod 322 and the connection portion 323.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that the embodiments of the present disclosure would be appropriately combined. The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more”. Further, “at least one of A, B, and C” should be interpreted to mean any of A, B, C, A+B, A+C, B+C, and A+B+C as well as to include combinations of the any thereof and any other than A, B, and C.

What is claimed is:

1. A gas laser device comprising:
a chamber device including a pair of electrodes at an internal space thereof to be filled with a laser gas and configured to output, through a window to an outside thereof, light generated from the laser gas when a voltage is applied to the electrodes;
a shutter arranged outside the chamber device and configured to be capable of shielding the light;
a movement mechanism capable of moving the shutter onto an optical path of the light and a first retraction position outside the optical path of the light; and
a coupling portion capable of coupling an optical component capable of receiving the light to the shutter,
the optical component being positioned on the optical path in a state in which the shutter is positioned at the first retraction position when the coupling portion is coupled to the optical component.

2. The gas laser device according to claim 1,
wherein the coupling portion can attach and detach the optical component in a state in which the shutter is positioned on the optical path.

3. The gas laser device according to claim 1,
wherein the optical component is an optical measurement instrument capable of measuring the light to be received.

4. The gas laser device according to claim 3,
wherein the optical measurement instrument is a power meter configured to measure power of the light.

5. The gas laser device according to claim 1,
wherein the coupling portion includes a hook member on which a projection provided at the optical component is hooked.

6. The gas laser device according to claim 1,
wherein the movement mechanism is capable of moving the shutter to a second retraction position opposite to the first retraction position side with respect to the optical path.

7. The gas laser device according to claim 6,
wherein the coupling portion can attach and detach the optical component in a state in which the shutter is positioned at the second retraction position.

8. An electronic device manufacturing method, comprising:
generating laser light using a gas laser device;
outputting the laser light to an exposure apparatus; and
exposing a photosensitive substrate to the laser light in the exposure apparatus to manufacture an electronic device, the gas laser device including:
a chamber device including a pair of electrodes at an internal space thereof to be filled with a laser gas and configured to output, through a window to an outside thereof, light generated from the laser gas when a voltage is applied to the electrodes;
a shutter arranged outside the chamber device and configured to be capable of shielding the light;
a movement mechanism capable of moving the shutter onto an optical path of the light and a first retraction position outside the optical path of the light; and
a coupling portion capable of coupling an optical component capable of receiving the light to the shutter, and
the optical component being positioned on the optical path in a state in which the shutter is positioned at the first retraction position when the coupling portion is coupled to the optical component.
